(19) United States
(12) Patent Application Publication
(10) Pub. No.: US 2026/0206631 A1
(43) Pub. Date: Jul. 16, 2026

(54) THERMAL COMPRESSION BONDING METHOD AND A COMPRESSION HEAD FOR PERFORMING SUCH METHOD

(71) Applicant: STATS ChipPAC Management Pte. Ltd., Singapore (SG)

(72) Inventor: JongChan PARK, Incheon (KR)

(21) Appl. No.: 19/450,597

(22) Filed: Jan. 15, 2026

(30) Foreign Application Priority Data
Jan. 15, 2025 (CN) 202510064580.9

(51) Int. Cl. H10W 72/00

(52) U.S. Cl. CPC H10W 72/07232; H10W 72/07141; H10W 72/07163; H10W 72/07236; H10W 72/07252

(57) ABSTRACT

Provided is a method for performing thermal compression bonding, comprising: providing a compression head with a bottom surface coated with a transition layer comprising at least one phase change material; providing a die with a bottom surface attached with one or more bumps; displacing the die onto a substrate such that the bumps contact the substrate; pressing the die against the substrate using the compression head, with the transition layer in contact with the die; and heating the bumps to a molten state through heat transferred from the compression head to the die, while the phase change material is heated to a temperature higher than a first transition temperature, at which a phase transition of the phase change material begins, to soften the phase change material, such that a contact area between the transition layer and the die increases as the transition layer is pressed.

### TECHNICAL FIELD

The present application generally relates to semiconductor technologies, and more particularly, to a thermal compression bonding method and a compression head for performing the thermal compression bonding method.

### BACKGROUND OF THE INVENTION

The semiconductor industry faces ongoing integration challenges as consumers demand electronic products that are lighter, smaller, and offer higher performance with increased functionality. In response, advanced packaging technologies such as flip-semiconductor die, semiconductor die stack packaging and wafer-level packaging (WLP) have become increasingly popular, as they can help maximize semiconductor die density and functionality in compact form factors.

In some typical advanced packaging technologies, a semiconductor die is typically interconnected with a substrate through global interconnection structures such as solder bumps or penetration electrodes, rather than relying on peripheral interconnections like lead frames or bonding wires. A common process for forming solder bumps between the semiconductor die and the substrate is thermal compression bonding. In this process, the semiconductor die is displaced on the substrate, and a compression head applies a force or pressure while heat is transferred to the solder material, causing it to melt and then form solidified bumps after a subsequent cooling phase. The thermal compression bonding process offers several advantages, including miniaturization, low thermal budget, material compatibility, and improved performance. However, it is noted that some failures such as false bonding may still occur to devices or packages formed using such bonding process.

Therefore, there is a need for an improved thermal compression bonding method.

### SUMMARY OF THE INVENTION

The objective of the present application is to provide an improved thermal compression bonding method and a new compression head, offering enhanced heat transfer between the compression head and a semiconductor die during a bonding process.

According to an aspect of the present application, a method for performing thermal compression bonding is provided, comprising: providing a compression head, wherein a bottom surface of the compression head is coated with a transition layer comprising at least one phase change material; providing a semiconductor die, wherein a bottom surface of the semiconductor die is attached with one or more solder bumps; displacing the semiconductor die onto a substrate such that the one or more solder bumps contact a top surface of the substrate; pressing the semiconductor die against the substrate using the compression head, with the transition layer of the compression head in contact with a top surface of the semiconductor die; and heating the one or more solder bumps to a molten state through heat transferred from the compression head to the semiconductor die, while the phase change material is heated to a temperature higher than a first transition temperature, at which a phase transition of the phase change material begins, to soften the phase change material, such that a contact area between the transition layer and the semiconductor die increases as the transition layer is pressed.

According to another aspect of the present application, a compression head for performing thermal compression bonding is provided, comprising: a main body, wherein the main body is configured to press an object to be bonded, with a bottom surface of the main body contacting a top surface of the object, while transferring heat to the object to bond the object to a base by a thermal compression bonding process; a transition layer coated on the bottom surface of the main body, wherein the transition layer comprises at least one phase change material; and a heater thermally contacting with the main body, wherein the heater is configured to heat the phase change material in the transition layer to a temperature higher than a first transition temperature, at which a phase transition of the phase change material begins, to soften the phase change material during the thermal compression bonding process, such that a contact area between the transition layer and the semiconductor die increases as the transition layer is pressed.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1A illustrates a structural diagram of a compression head pressing a semiconductor die onto a substrate in a thermal compression bonding process.

FIG. 1B illustrates an enlarged view of a region A in FIG. 1A.

FIG. 2A illustrates a structural diagram of a compression head for performing a thermal compression bonding process according to an embodiment of the present application.

FIG. 2B illustrates an enlarged view of a region B in FIG. 2A.

FIG. 2C illustrates an enlarged view of a region C in FIG. 2A.

FIG. 3 illustrates a method for performing thermal compression bonding according to an embodiment of the present application.

FIGS. 4A to 4D illustrate sectional views of steps of the method shown in FIG. 3 according to an embodiment of the present application.

The same or similar reference numbers will be used throughout the drawings to refer to the same or corresponding parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the Figures. The spatially relative terms are intended to encompass different orientations of the device in use or operation in addition to the orientation depicted in the Figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As aforementioned, some failures such as false bonding may occur to devices or packages formed using thermal compression bonding processes. In particular, it is found that uneven contacting surfaces between a compression head and a semiconductor die can result in a lower thermal conductivity and unsatisfactory heat transfer in an interface between them, which may affect bonding efficiency or causing bonding failures.

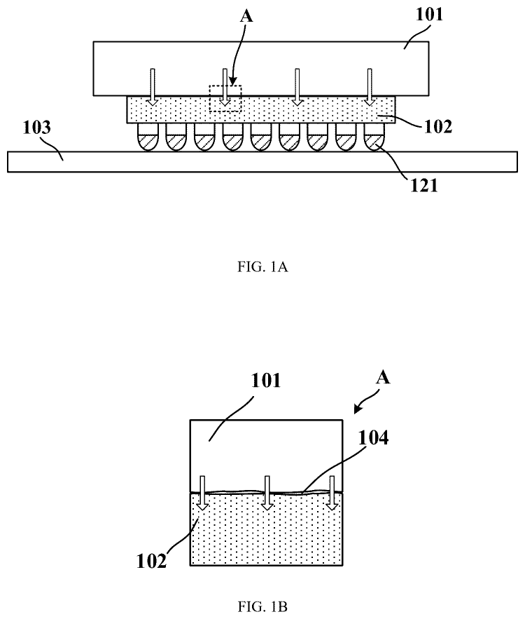

Referring to FIG. 1A, a structural diagram of a conventional compression head 101 pressing a semiconductor die 102 onto a substrate 103 in a thermal compression bonding process is shown. Specifically, heat is transferred from the compression head 101 to the semiconductor die 102 in a direction shown by the arrows, then to solder bumps 121 between the semiconductor die 102 and the substrate 103, causing them to melt. After the bonding process, the melted solder bumps 121 can be cooled down and solidify into respective solder bumps, forming a connection between the semiconductor die 102 and the substrate 103. FIG. 1B is an enlarged view of a region A in FIG. 1A, illustrating an interface between the compression head 101 and the semiconductor die 102. As shown in FIG. 1B, due to the unevenness of a bottom surface of the compression head 100 and/or a top surface of the semiconductor die 102, gaps or voids 104 may form at the interface between the compression head 101 and the semiconductor die 102. These gaps or voids 104 may deteriorate heat transfer from the compression head 101 to the semiconductor die 102.

The poor interface produced from uneven contacting surfaces cannot be addressed by applying a greater compression force which may introduce greater deformation, because the greater force, if applied, may not only deform the compression head but also the solder bumps beneath the semiconductor die. In particular, in order to accommodate electronic components on a limited area of a substrate, a layout of the components on the substrate needs to be carefully designed and narrow gaps may be maintained between conductive pads to assure electrical isolation between components which are adjacent to each other. However, solder bumps printed or other dispensed on adjacent conductive pads may deform too much to connect with each other and form solder bridges after the thermal bonding process, leading to undesired electrical connections such as short circuits.

In order to address the above issue, a new thermal compression bonding method for forming solder bumps is proposed in the present application. The method can prevent significant reshaping of solder bumps during the bonding or reflowing process, and thus avoid undesired solder bridges or short circuits.

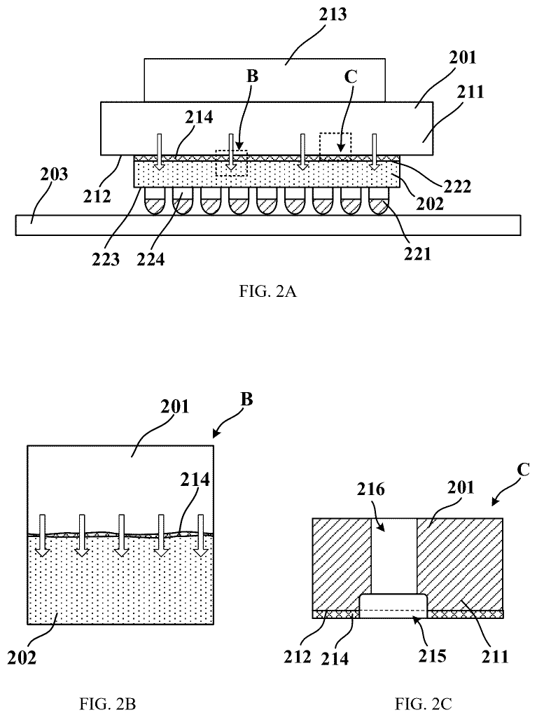

FIG. 2A illustrates a structural diagram of a compression head 201 for performing a thermal compression bonding process according to an embodiment of the present application. FIG. 2B illustrates an enlarged view of a region B in FIG. 2A. FIG. 2C illustrates an enlarged view of a region C in FIG. 2A.

Referring to FIG. 2A, the compression head 201 includes a main body 211 with a bottom surface 212 for pressing an object, such as a semiconductor die 202, onto a base such as a substrate 203 shown in FIG. 2A. The compression head 201 also includes a heater 213 thermally connected to the main body 211, which can generate heat to heat the main body 211. In some embodiments, the heater 213 may be embedded within the main body 211 of the compression head 201. As the semiconductor die 202 is pressed by the main body 211 onto the substrate 203, heat generated by the heater 213 can be transferred to solder bumps 221 below the semiconductor die 202 via the main body 211 and the semiconductor die 202. As a result, the solder bumps 221 may melt while being pressed. The semiconductor die 202 and the substrate 203 can be connected together through the solder bumps 221. Subsequently, after the solder bumps 221 solidify into solder bumps, the semiconductor die 202 is bonded to the substrate 203. In some embodiments, conductive pads 224 may formed on a bottom surface 223 of the semiconductor die 202 and/or on a top surface of the substrate 203 for the mounting of the solder bumps 221.

The main body 211 may be secured to the heater 213 in various manner. In some embodiments, a mechanical securing member, such as a bolt or screw, may be used to secure the main body 211 to the heater 213. Alternatively, the main body 211 may be detachably secured to the heater 213, enabling possibility of exchanging different types of main bodies (e.g., with different sizes or different shapes) to meet various bonding requirements.

The main body 211 may be made of a material with sufficient thermal conductivity to effectively transfer heat from the heater 213 to the object to be processed, as well as sufficient strength to withstand the external compression force. In some embodiments, the main body 211 may be made of stainless steel and/or a ceramic material like silicon carbide (SiC), both of which have relatively high thermal conductivity and strength. In some embodiments, the main body 211 may be shaped as a cuboid, a cylinder or a hexahedron according to the configuration of the object or semiconductor die to be processed.

The heater 213 may include an electric heating element that generates heat from an electrical power supply. In some embodiments, the heater 213 may include a planar heat electrode layer made of a nickel-based alloy, which allows heat to be generated uniformly across the heat electrode layer, ensuring uniform heat transfer to the main body 211. In some other embodiments, the heater 213 may incorporate other types of heating elements suitable for generating and transferring heat to the main body 211, such as ceramic heaters and electric coil heaters.

As shown in FIG. 2A, a transition layer 214 is coated on the bottom surface 212 of the main body 211, which includes at least one phase change material (PCM). The phase change material is a material that absorbs or releases sufficient energy during a phase transition to provide useful heating or cooling. When the phase change material undergoes a phase transition, it typically shifts between solid and liquid states. A solidus temperature for the phase change material is the highest temperature at which the material remains entirely solid. Below this solidus temperature, the material is fully solid. A liquidus temperature for the phase change material is the lowest temperature at which the material is entirely liquid. Above this temperature, the material is fully liquid. For example, if a phase change material has a solidus temperature of 200° C. and a liquidus temperature of 400° C., the material may start phase transition from solid state to liquid state as it reaches 200° C., but may still be partially solid. Once it reaches 400° C., it can be fully liquid.

In addition to the solid-to-liquid phase transition, some phase change materials can undergo transitions between non-classical states, such as changes in crystalline structure. In these cases, the material shifts from one crystalline form to another, potentially resulting in a higher or lower energy state. For example, solid-solid phase change materials (solid-solid PCMs) may undergo a solid-to-solid phase transition, during which they can absorb or release significant amounts of heat. These materials change their crystalline structure from one lattice configuration to another, such as transitioning from crystalline form to amorphous structure, at a fixed and well-defined temperature.

During the thermal compression bonding process, the heater 213 can heat the phase change material of the transition layer 214 to a temperature higher than a first transition temperature, at which a phase transition of the phase change material begins. This phase transition may involve a change from solid state to liquid state or from one crystalline structure to another structure, which softens the phase change material, i.e., the phase change material can be more flexible and deform more if applied with a compression pressure or force. Under such condition, as shown in FIG. 2B, since the transition layer 214 is under compression during the thermal compression bonding process, the softened phase change material causes the transition layer 214 to extend and fill small gaps or voids between the main body 211 and the semiconductor die 202, which increases the contact area between them. Therefore, the compression head 201 can provide improved heat transfer performance and reduce non-uniformity of heat transfer between the main body 211 and the semiconductor die 202.

In some embodiments, the phase change material is a solid-liquid phase change material, and the first transition temperature is the solidus temperature of the material. Under such condition, the heater can heat the phase change material to a temperature higher than its solidus temperature, causing it to transition from solid state to liquid state and soften as it partially becomes liquid. In some embodiments, the heater 213 can heat the phase change material to a temperature higher than its solidus temperature but lower than its liquidus temperature. As a result, the phase change material does not fully transition to the liquid state, which may avoid serious material consumption and liquid handling issues during the thermal compression bonding processes. Upon subsequent cooling, the phase change material can return to the solid state once the temperature drops below its solidus temperature.

In some embodiments, the phase change material is a solid-solid phase change material (solid-solid PCM), and the heater 213 can heat the solid-solid phase change material in the transition layer 214 to a temperature at which its crystalline structure is at least partially converted to another crystalline structure during the thermal compression bonding process. For example, the heater 213 can heat the solid-solid phase change material to a temperature at which its crystalline structure is at least partially converted to an amorphous structure with a lower hardness, and thus the solid-solid phase change material softens. As mentioned before, the softened transition layer 214 can fill the gaps and voids between the main body 211 and the semiconductor die 202, such that the contact area between them increases.

In some embodiments, the first transition temperature is selected from a range of 200° C. to 260° C. For example, the phase change material in the transition layer 214 can be a solid-liquid phase change material with a solidus temperature ranging from 200° C. to 260° C., or a solid-solid phase change material with a transition temperature, at which the crystalline structure begins to change, ranging from 200° C. to 260° C. With this temperature range, the compression head 201 and the semiconductor die 202 can form a hermetic junction interface during the bonding process, thereby enhancing heat flow efficiency. It should be noted that the solidus temperature or transition temperature can be adjusted by mixing different phase change materials or modifying the composition of the phase change material. Furthermore, the heater 213 can operate at any suitable temperature to ensure the melting of the solder bumps 221 and the phase transition of the phase change material in the transition layer 214.

In some embodiments, the phase change material in the transition layer may be a nitrate salt mixture consisting of 60 wt % NaNO₃ and 40 wt % KNO₃. The nitrate salt mixture may have a solidus temperature around 220° C. In some other embodiments, the phase change material in the transition layer may be formed by mixing 1 wt % of SiO 2 or Al₂O₃ with a nitrate salt mixture consisting of 60 wt % NaNO₃ and 40 wt % KNO₃. The resulting material may have a solidus temperature around 210° C. However, the SiO₂ or Al₂O₃ in the material may be replaced by other additives, such as graphene, CNTs, MgO. In other embodiments, the base materials of the phase change material may include paraffin, fatty acids, esters, or sugar alcohol.

In some embodiments, the phase change material in the transition layer 214 is a composite phase change material, formed by mixing one or more phase change materials. The melting and solidification temperatures of the composite phase change material can be adjusted by changing respective ratios of different phase change materials. For example, the composite phase change material may include two phase change materials with different solidus and/or liquidus temperatures. In some embodiments, the composite phase change material may also include one or more highly conductive materials, such as graphite, carbon nanotubes, nanoparticles, or copper mesh, to enhance the thermal conductivity of the material.

In some embodiments, the phase change material is paraffin-based or liquid metal-based. Unlike epoxy-based phase change materials, which may adhere to the silicon surface of the semiconductor die 202 due to homogeneity, the transition layer 214 with paraffin-based or liquid metal-based materials is easier to be detached from the silicon surface while keep adhering to the main body 211. This allows the transition layer 214 to be used for a longer period. It should be noted that the thickness of the transition layer 214 can be set based on the demand on thermal conductivity and other properties of the transition layer 214, and/or unevenness of the surfaces of the compression head and the semiconductor die. In some embodiments, the transition layer 214 may have a thickness less than 1 mm. During the thermal compression bonding process, when pressure is applied, the thickness of the transition layer 214 is reduced to no less than 10% of its original thickness, facilitating the filling of gaps and voids between the compression head and the semiconductor die.

In some embodiments, the transition layer 214 includes one or more openings in fluid communication with a vacuum source via one or more channels in the main body 211, such that negative pressure can be generated at the one or more second openings, facilitating attraction of the semiconductor die 202 by the compression head. FIG. 2C illustrates a sectional view of an area C in FIG. 2B, showing an opening 215 in the transition layer 214. The opening 215 is connected to a vacuum source (not shown) via a channel 216 formed in the main body 211. As a result, a negative pressure can be created at the openings 215. When the compression head 201 contacts the semiconductor die 202 as shown in FIG. 2A, the negative pressure can be used to attract and pick up the semiconductor die 202. It should be noted that the opening 215 and channel 216 shown in FIG. 2C are for illustration purpose only and not limiting. The main body 211 and the transition layer 214 can have channels and openings of any other suitable shapes, which can be arranged in any suitable layouts to secure the semiconductor die 202 with the compression head.

In some embodiments, the compression head 201 is connected to an actuator and a power source, which can be controlled to move the main body 211 to pick up and displace the semiconductor die 202. The heater 213 may be used to generate heat prior to the compression head 201 picking up the semiconductor die 202. In some embodiments, a coolant channel (not shown) may also be provided within the main body 211. When the solder bumps 221 of the semiconductor die 202 are melted and attached to the substrate 203, the coolant can be circulated through the main body 211 to help with cooling the main body 211 as well as solidifying the solder bumps. Additionally, the coolant can also help to cool the phase change material in the transition layer 214. As a result, the phase change material undergoes a reversed phase transition and becomes hardened, allowing the compression head 201 to be detached from the semiconductor die 202 more easily.

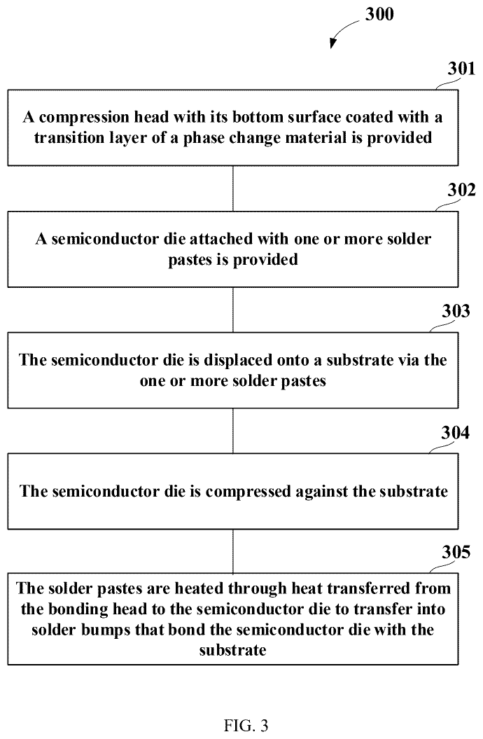

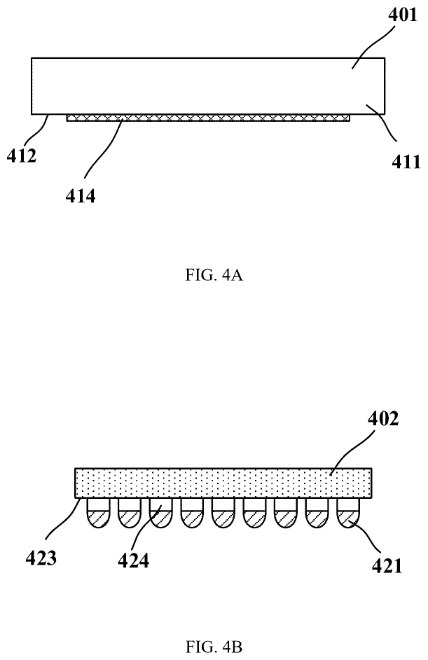

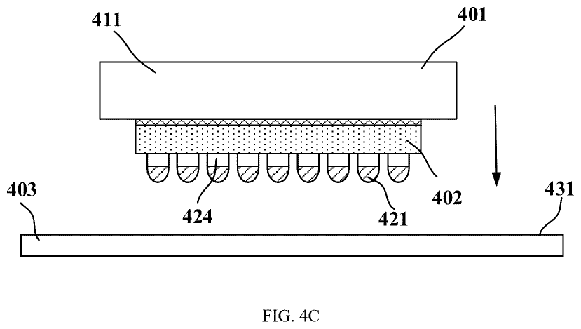

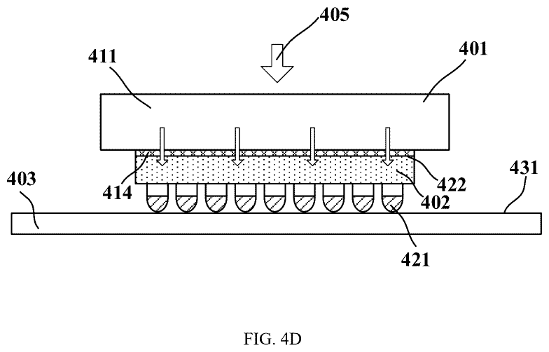

FIG. 3 illustrates a method for performing thermal compression bonding according to an embodiment of the present application. FIGS. 4A to 4D illustrate sectional views of steps of the method shown in FIG. 3 according to an embodiment of the present application.

As shown in FIG. 3, the method 300 begins with step 301 where a compression head is provided. The compression head has a bottom surface coated with a transition layer including at least one phase change material. In step 302, a semiconductor die is provided, and a bottom surface of the semiconductor die is attached with one or more solder bumps. In step 303, the semiconductor die is displaced onto a substrate so that the one or more solder bumps make contact with a top surface of the substrate. In step 304, the semiconductor die is pressed against the substrate using the compression head, with the transition layer of the compression head being in contact with a top surface of the semiconductor die.

Next, in step 305, the one or more solder bumps are heated to a molten state through heat transferred from the compression head to the semiconductor die. During this heating step, the phase change material in the transition layer is heated to a temperature higher than its first transition temperature which leads to a softened state of the phase change material. As mentioned previously, the first transition temperature is the temperature at which the phase transition of the phase change material begins. Once softened, the transition layer can extend and fill the gaps and voids between the compression head and the semiconductor die upon compression by the compression head, thereby increasing the contact area between them. The steps of the method 300, as shown in FIG. 3, will be further illustrated in detail with reference to FIGS. 4A to 4D below.

Specifically, as shown in FIG. 4A, a compression head 401 is provided, which includes a main body 411 with a bottom surface 412 for pressing an object to be bonded, such as a semiconductor die, onto a base, such as a substrate. A transition layer 414, which includes at least one phase change material, is coated on the bottom surface 412 of the main body 411.

Referring to FIG. 4B, a semiconductor die 402 is provided, with several solder bumps 421 attached to the bottom surface 421 of the semiconductor die 402. It should be noted that the thermal compression bonding method described herein can also be used to bond other electronic components. In some embodiments, additional conductive pads 424 may be formed on a bottom surface 423 of the semiconductor die 402 for the mounting of the solder bumps 421.

As shown in FIG. 4C, the semiconductor die 402 is displaced onto a substrate 403, such that the solder bumps 421 can contact a top surface 431 of the substrate 403. The compression head 401 may include several openings where a negative pressure can be generated to attract and pick up the semiconductor die 402. Additionally, the compression head 401 may also include an actuator and a power source to move the compression head 401 to a first position to pick up the semiconductor die 402 and displace it onto the substrate 403.

Next, as shown in FIG. 4D, the semiconductor die 402 is pressed against the substrate 403 using the compression head 401 in a direction as shown by the big arrow 405. The transition layer 414 of the compression head 401 can be in contact with the top surface 422 of the semiconductor die 402. Meanwhile, the solder bumps 421 are heated to a molten state through heat transferred from the compression head 401 to the semiconductor die 402. During this process, the phase change material in the transition layer 414 is heated to a temperature higher than the first transition temperature, at which the phase transition of the phase change material begins, to soften the phase change material. The softened phase change material causes the transition layer 414 to extend and fill the gaps and voids between the compression head 401 and the semiconductor die 402 under compression. Consequently, the contact area between the transition layer 414 and the semiconductor die 402 increases as the transition layer 414 is being pressed.

In some embodiments, the thermal compression bonding method 300 may further include a pre-heating step. Specifically, the compression head 401 may be heated to a certain temperature before picking up the semiconductor die 402 or before pressing the semiconductor die 402 against the substrate 403, so as to save time and improve efficiency. In some embodiments, the thermal compression bonding method may also include a subsequent cooling step to solidify the melted solder bumps. Meanwhile, this cooling step also allows the phase change material to undergo a reversed phase transition and become hardened, enabling the compression head 401 to be detached more easily from the semiconductor die 402, with less material from the transition layer 414 remaining attached to the semiconductor die 402. The cooling step can be a passive cooling step, or, in some cases, be an active cooling step. For example, as mentioned previously, a coolant channel may be provided within the compression head 401. When the solder bumps of the semiconductor die 402 are melted and bonded to the substrate 403, coolant may be circulated through the coolant channel to help solidify both the melted solder bumps and the phase change material.

In some embodiments, the thermal compression bonding method may also include a phase change material application step to form the transition layer 414 on the bottom surface of the compression head 401. Specifically, a portion of the transition layer 414 may adhere to the top surface of the semiconductor die 402 after the transition layer 414 is detached, causing the transition layer 414 to be partially transferred. To maintain the increased contact area formed by the transition layer 414, the phase change material application step may be performed before each bonding operation to repair the transition layer 414. In some embodiments, the transition layer 414 can be repaired by spraying, sputtering, or using other coating methods to apply the phase change material to the transition layer 414. In some other embodiments, the transition layer 414 may be a disposable layer, which can be replaced after each thermal compression bonding process or after every two to three thermal compression bonding operations.

Due to the presence of the transition layer, which includes at least one phase change material coated on the bottom surface of the compression head, the contact area between the compression head and the object to be bonded, such as the semiconductor die, increases. This results in improved heat transfer efficiency and reduced non-uniformity of heat transfer between the compression head and the semiconductor die.

The discussion herein included numerous illustrative figures that showed various portions of a thermal compression bonding process and a compression head for implement the process. For illustrative clarity, such figures did not show all aspects of each example assembly. Any of the example assemblies and/or methods provided herein may share any or all characteristics with any or all other assemblies and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for performing thermal compression bonding, comprising:
providing a compression head, wherein a bottom surface of the compression head is coated with a transition layer comprising at least one phase change material;
providing a semiconductor die, wherein a bottom surface of the semiconductor die is attached with one or more solder bumps;
displacing the semiconductor die onto a substrate such that the one or more solder bumps contact a top surface of the substrate;
pressing the semiconductor die against the substrate using the compression head, with the transition layer of the compression head in contact with a top surface of the semiconductor die; and
heating the one or more solder bumps to a molten state through heat transferred from the compression head to the semiconductor die, while the phase change material is heated to a temperature higher than a first transition temperature, at which a phase transition of the phase change material begins, to soften the phase change material, such that a contact area between the transition layer and the semiconductor die increases as the transition layer is pressed.

2. The method of claim 1, wherein the first transition temperature is a solidus temperature of the phase change material, and in the step of heating the one or more solder bumps, the phase change material is heated to a temperature higher than the solidus temperature and lower than a liquidus temperature of the phase change material.

3. The method of claim 1, wherein the first transition temperature is a temperature selected from the range of 200° C. to 260° C.

4. The method of claim 1, wherein the phase change material is a composite phase change material.

5. The method of claim 4, wherein the composite phase change material comprises graphite, carbon nanotube, nano particles or coper mesh.

6. The method of claim 1, wherein the phase change material is a solid-solid phase change material.

7. The method of claim 6, wherein the first transition temperature is a temperature at which a crystalline structure of the solid-solid phase change material begins to change to a different crystalline structure.

8. The method of claim 7, wherein the different crystalline structure is an amorphous structure.

9. (canceled)

10. The method of claim 1, wherein a thickness of the transition layer is less than 1 mm.

11. The method of claim 1, wherein the transition layer comprises one or more openings in fluid communication with a vacuum source via one or more channels in the compression head, and the step of displacing the semiconductor die onto the substrate comprises:
displacing the compression head onto the semiconductor die with the transition layer contacting the top surface of the semiconductor die;
picking up the semiconductor die via negative pressure generated at the one or more openings of the transition layer; and
displacing the semiconductor die onto the substrate, such that the one or more solder bumps contact the top surface of the substrate.

12. A compression head for performing thermal compression bonding, comprising:
a main body, wherein the main body is configured to press an object to be bonded, with a bottom surface of the main body contacting a top surface of the object, while transferring heat to the object to bond the object to a base by a thermal compression bonding process;
a transition layer coated on the bottom surface of the main body, wherein the transition layer comprises at least one phase change material; and
a heater thermally contacting with the main body, wherein the heater is configured to heat the phase change material in the transition layer to a temperature higher than a first transition temperature, at which a phase transition of the phase change material begins, to soften the phase change material during the thermal compression bonding process, such that a contact area between the transition layer and the object increases as the transition layer is pressed.

13. The compression head of claim 12, wherein the first transition temperature is a solidus temperature of the phase change material, and the phase change material is heated to a temperature higher than the solidus temperature and lower than a liquidus temperature of the phase change material during the thermal compression bonding process.

14. The compression head of claim 13, wherein the first transition temperature is a temperature selected from the range of 200° C. to 260°C.

15. The compression head of claim 12, wherein the phase change material is a composite phase change material.

16. The compression head of claim 15, wherein the composite phase change material comprises graphite, carbon nanotube, nano particles or coper mesh.

17. The compression head of claim 12, wherein the phase change material is a solid-solid phase change material.

18. The compression head of claim 17, wherein the first transition temperature is a temperature at which a crystalline structure of the solid-solid phase change material begins to change to a different crystalline structure.

19. The compression head of claim 18, wherein the different crystalline structure is an amorphous structure.

20. (canceled)

21. The compression head of claim 12, wherein a thickness of the transition layer is less than 1 mm.

22. The compression head of claim 12, wherein the transition layer comprises one or more openings in fluid communication with a vacuum source via one or more channels in the main body, such that negative pressure can be generated at the one or more openings to pick up the object to be bonded.
